(19) United States
(12) Patent Application Publication
(10) Pub. No.: US 2012/0313679 A1
(43) Pub. Date: Dec. 13, 2012

(54) PUMP CIRCUIT AND METHOD FOR PUMPING VOLTAGE IN SEMICONDUCTOR APPARATUS

(75) Inventor: Chae Kyu JANG, Icheon-si (KR)

(73) Assignee: HYNIX SEMICONDUCTOR INC., Icheon-si (KR)

(21) Appl. No.: 13/341,004

(22) Filed: Dec. 30, 2011

(30) Foreign Application Priority Data
Jun. 8, 2011 (KR) 10-2011-0055150

(51) Int. Cl. H03L 7/093

(52) U.S. Cl. 327/157

(57) ABSTRACT

A pump circuit includes a first clock generation unit, a second clock generation unit and a pumping stage unit. The first clock generation unit is configured to generate a first clock with a first amplitude by using an input clock and an external voltage. The second clock generation unit is configured to generate a second clock with a second amplitude larger than the first amplitude by using the input clock and an amplified voltage generated by amplifying the external voltage. The pumping stage unit is configured to increase an input voltage using the first clock and the second clock and generate amplified output voltages.

### CROSS-REFERENCES TO RELATED APPLICATION

The present application claims priority under 35 U.S.C. §119(a) to Korean application number 10-2011-0055150, filed on Jun. 8, 2011, in the Korean Intellectual Property Office, which is incorporated herein by reference in its entirety.

### BACKGROUND

1. Technical Field

The present invention relates generally to a semiconductor apparatus, and more particularly to a semiconductor apparatus including a pump circuit.

2. Related Art

In a semiconductor apparatus, a high voltage may be used for a certain operation. For example, in a semiconductor memory apparatus such as a DRAM (dynamic random access memory), a high voltage may be used to control a word line.

A nonvolatile memory apparatus, in particular, a flash memory apparatus programs or erases data in or from a cell transistor using an F-N (Fowler-Nordheim) tunneling mechanism, and at this time, a high voltage (for example, 20V) higher than a power supply voltage is needed. Also, when performing a read operation, a certain level of voltage (for example, 5V to 8V) is needed although it is lower than the high voltage.

In order to obtain a high voltage higher than a power supply voltage, a semiconductor apparatus has a pump circuit. In general, the pump circuit is configured such that a plurality of stages coupled in series sequentially amplifies the power supply voltage.

### SUMMARY

A pump circuit which occupies a smaller area and generates less noise is described herein.

In one embodiment of the present invention, a pump circuit includes: a first clock generation unit configured to generate a first clock with a first amplitude by using an input clock and an external voltage; a second clock generation unit configured to generate a second clock with a second amplitude larger than the first amplitude by using the input clock and an amplified voltage; and a pumping stage unit configured to pump an amplification input voltage using the first clock and the second clock and generate amplified output voltages.

In another embodiment of the present invention, a pump circuit includes a plurality of pumping stages connected in series, wherein first group pumping stages of the plurality of pumping stages perform pumping operations using a first clock which oscillates with a first amplitude, and wherein second group pumping stages of the plurality of pumping stages perform pumping operations using a second clock which oscillates with a second amplitude larger than the first amplitude.

In another embodiment of the present invention, a method for pumping a voltage in a semiconductor apparatus includes; receiving an amplification input voltage; outputting a first amplified voltage by pumping the amplified input voltage using a second clock with a second amplitude; and outputting a second amplified voltage by pumping the first amplified voltage using a first clock with a first amplitude smaller than the second amplitude.

### BRIEF DESCRIPTION OF THE DRAWINGS

Features, aspects, and embodiments are described in conjunction with the attached drawings, in which:

FIG. 1 is a schematic block diagram illustrating a pump circuit in accordance with an embodiment of the present invention;

FIG. 2 is a block diagram illustrating a pump circuit in accordance with an embodiment of the present invention;

FIG. 3 is a block diagram illustrating an exemplary embodiment of the amplified voltage generation unit shown in FIG. 2;

FIG. 4 is a block diagram illustrating an exemplary embodiment of the pumping stage unit shown in FIG. 2; and

FIG. 5 is a block diagram illustrating an exemplary embodiment of each of the second group pumping stages and the first group pumping stages shown in FIG. 4.

### DETAILED DESCRIPTION

Hereinafter, a pump circuit and a method for pumping a voltage in a semiconductor apparatus according to the present invention will be described below with reference to the accompanying drawings through exemplary embodiments.

FIG. 1 is a schematic block diagram illustrating a pump circuit in accordance with an embodiment of the present invention. The pump circuit shown in FIG. 1 includes 8 pumping stages 11 to 18 which are coupled in series. The respective pumping stages 11 to 18 increase the voltages inputted thereto by using an amplification clock clka and output boosted voltages. The first pumping stage 11 receives an input voltage vi.

A voltage amplification va in each of the pumping stages 11 to 18, corresponding to the difference between an input voltage and an output voltage, is determined by the amplitude of the amplification clock clka. For example, in the case where the amplification clock clka oscillates with an amplitude between an external voltage VDD and a ground voltage VSS (=0V), the voltage amplification va in each of the pumping stages 11 to 18 corresponds to the external voltage VDD. The voltage amplification va may be ‘the external voltage VDD minus the threshold voltage of a transistor’, depending upon a design of the respective pumping stages 11 to 18.

The pump circuit shown in FIG. 1 is configured to output, to an outside, output voltages vo and vo1 of the third pumping stage 13 and the eighth pumping stage 18. Since the voltage amplification va of each pumping stage is maintained constant, the output voltage vo becomes vi+3va, and the output voltage vo1 becomes vo+5va, that is, vi+8va.

It is assumed that the amplification input voltage vi is 3V, the voltage amplification va of each pumping stage is 3V and a desired output voltage is 33V. In this case, the pump circuit should have at least 10 pumping stages.

The large number of pumping stages may cause an increase in the area of a semiconductor apparatus. In order to realize the pump circuit occupying a smaller area, a method of increasing the voltage amplification va of each pumping stage may be used.

For example, it is assumed that the amplification input voltage vi is 3V, the voltage amplification va of each pumping stage is 6V and a desired output voltage is 33V. In this case, the pump is circuit should have at least 5 pumping stages.

In the case where the voltage amplification va of each pumping stage is increased in this way, while the number of desired pumping stages decreases, stability of the output voltage vo may deteriorate. In a semiconductor apparatus such as a flash memory apparatus, the output voltage vo of the pump circuit is used so as to program or erase data. Therefore, if a noisy output voltage vo is used, reliability in operations may deteriorate.

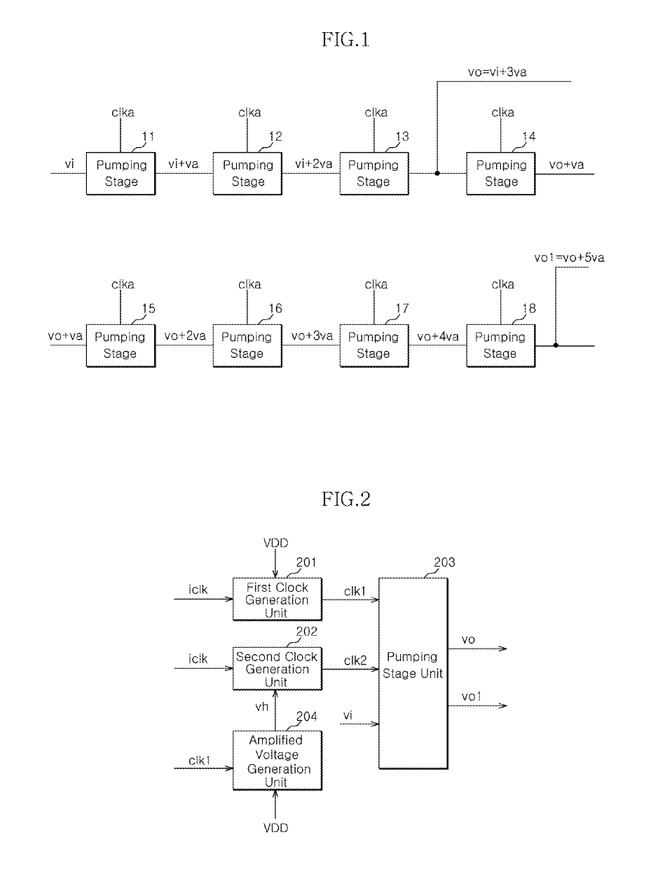

FIG. 2 is a block diagram illustrating a pump circuit in accordance with an embodiment of the present invention. The pump circuit shown in FIG. 2 includes a first clock generation unit 201, a second clock generation unit 202 and a pumping stage unit 203.

The first clock generation unit 201 is configured to generate a first clock clk1 with a first amplitude by using an input clock iclk and an external voltage VDD. For example, the first amplitude may correspond to the external voltage VDD.

The second clock generation unit 202 is configured to generate a second clock clk2 with a second amplitude by using the input clock iclk and an amplified voltage vh. For example, the amplified voltage vh may have a level corresponding to two times the external voltage VDD, and in this case, the second amplitude may correspond to two times the external voltage VDD.

In the embodiment of the present invention, it is exemplified that the first amplitude is smaller than the second amplitude.

The first clock generation unit 201 and the second clock generation unit 202 may be configured by level shift circuits which are generally known in the art.

The pumping stage unit 203 is configured to pump an input voltage vi using the first clock clk1 and the second clock clk2 and generate amplified output voltages vo and vo1.

In FIG. 2, although two amplified output voltages vo and vo1 are exemplified., the present invention is not limited thereto. Unlike the pump circuit shown in FIG. 1 which performs a pumping operation using the one kind of clock clka, the pumping stage unit 203 in accordance with an embodiment of the present invention performs a pumping operation using the two kinds of clocks clk1 and clk2 with two different amplitudes.

The pumping stage unit 203 performs two kinds of pumping operations. One of the pumping operations performed only for boosting a voltage (hereafter referred to as a boosting pumping operation). The other of the pumping operations is a pumping operation which is performed for boosting and outputting a voltage (hereafter referred to as an output pumping operation).

In the boosting pumping operation, the pumping stage unit 203 performs the pumping operation using a clock with a larger amplitude between the two kinds of clocks clk1 and clk2, for example, the second clock clk2.

In the output pumping operation, the pumping stage unit 203 performs the pumping operation using a clock with a smaller is amplitude between the two kinds of clocks clk1 and clk2, for example, the first clock clk1.

The pump circuit shown in FIG. 2 is configured to perform the pumping operations using the first clock clk1 and the second clock clk2. Therefore, the pumping stage unit 203 may reach the target levels of the output voltages vo and vo1 by performing a small number of times the pumping operation for boosting a voltage, that is, the boosting pumping operation, when compared to the case of performing a pumping operation using only one clock as in the pump circuit shown in FIG. 1. As a consequence, a space required for the pumping stage unit 203 may decrease.

The pumping stage unit 203 may output the output voltages vo and vo1 with reduced noise by performing the pumping operation for boosting and outputting a voltage, that is, the output pumping operation, thereby realizing a stable high voltage.

Also, as shown in FIG. 2, the pump circuit may further include an amplified voltage generation unit 204. The amplified voltage generation unit 204 is configured to generate the amplified voltage vh using the first clock clk1 and the external voltage VDD. The amplified voltage generation unit 204 may be configured to amplify the external voltage VDD using the first clock clk1 and generate the amplified voltage vh.

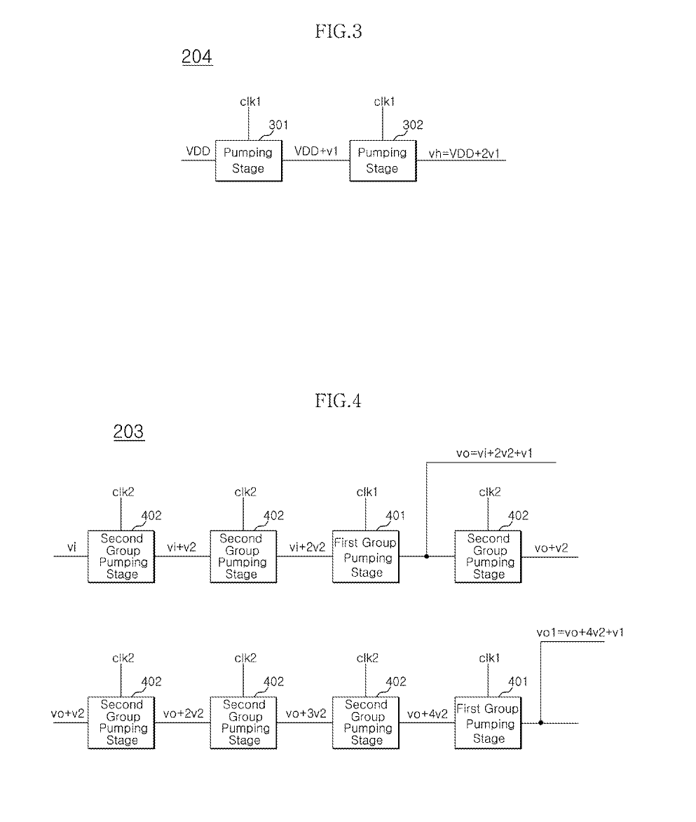

FIG. 3 is a block diagram illustrating an exemplary embodiment of the amplified voltage generation unit 204 shown in FIG. 2. The amplified voltage generation unit 204 may include one or is more of pumping stages 301 and 302 which are coupled in series.

For example, when assuming that the external voltage VDD is 3V, an amplification amount v1 by the pumping operation using the first clock clk1 is 3V and the desired amplified voltage vh is 9V, the amplified voltage generation unit 204 may be configured to include two pumping stages 301 and 302 which are coupled in series, as shown in FIG. 3. However, it is to be noted that this represents a mere example and the number of necessary pumping stages may vary depending upon the voltage amplification v1 and the desired level of the amplified voltage vh.

In general, a pumping stage performs a pumping operation for a capacitor element arranged therein, in synchronization with a preset clock signal. Thus, the capacitor elements arranged in the one or more of pumping stages 301 and 302 may have an ONO (oxide-nitride-oxide) structure.

The ONO structure defines a device constituted by an oxide, a nitride and an oxide, and provides an advantage in that it occupies a reduced area to provide the same capacitance when compared to other capacitor elements. However, the ONO structure has a disadvantage that a breakdown voltage as a durability index with regard to the voltages applied to both ends thereof is low. Since the amplified voltage vh is a relatively low voltage when compared to the output voltages vo and vo1, it is advantageous in terms of space efficiency to form the capacitor elements to have the ONO structure.

Therefore, the capacitor elements arranged in both pumping stages 301 and 302 constituting the amplified voltage generation unit 204 or the capacitor element, arranged in the pumping stage 301 which amplifies a voltage of a lower level, may be formed to have the ONO structure and thereby may reduce the area occupied by the pump circuit.

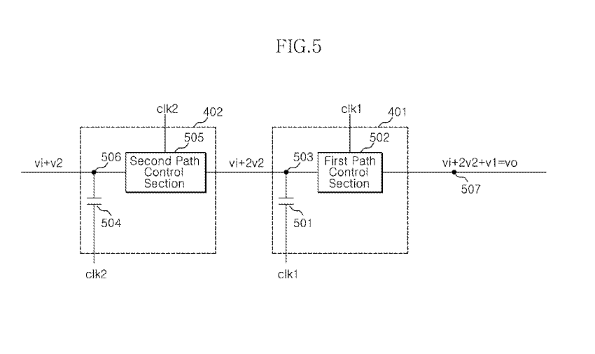

FIG. 4 is a block diagram illustrating an exemplary embodiment of the pumping stage unit 203 shown in FIG. 2. The pumping stage unit 203 includes a plurality of pumping stages 401 and 402 which are coupled in series. In FIG. 4, it is exemplified that the pumping stage unit 203 includes, without a limiting sense, 8 pumping stages 401 and 402. The initial pumping stage among the 8 pumping stages 401 and 402, which are coupled in series, receives the amplification input voltage vi.

First group pumping stages 401 among the plurality of pumping stages 401 and 402 perform pumping operations using the first clock clk1. The first group pumping stages 401 output input voltages by boosting the levels thereof by a first voltage amplification v1 through the pumping operations using the first clock clk1.

Second group pumping stages 402 among the plurality of pumping stages 401 and 402 perform pumping operations using the second clock clk2. The second group pumping stages 402 output input voltages by boosting the levels thereof by a second voltage amplification v2 through the pumping operations using the second clock clk2.

The first amplitude of the first clock clk1 is smaller than the is second amplitude of the second clock clk2, and accordingly, the first voltage amplification v1 is smaller than the second voltage amplification v2. For example, the first amplitude may be 3V and the second amplitude may be 6V. Thus, the first voltage amplification v1 is 3V and the second voltage amplification v2 is 6V.

Because the first group pumping stages 401 and the second group pumping stages 402 perform the pumping operations by being coupled in series, the cycles and phases of the first clock clk1 and the second clock clk2 may be the same with each other.

As can be seen from FIG. 2, the first clock generation unit 201 and the second clock generation unit 202 generate the first clock clk1 and the second clock clk2 using the input clock iclk. Hence, generation of the first clock clk1 and the second clock clk2 with the same phase and cycle may be easily implemented.

The output voltages vo and vo1 of the first group pumping stages 401 may be outputted to an outside of the pump circuit. The output voltages vo and vo1 of the first group pumping stages 401 have levels boosted by the first voltage amplification v1 when compared to their respective input voltages vi+2v2 and vo+4v2. Thus, the second group pumping stages 402 with the second voltage amplification v2 have reduced noise when considering output voltages thereof vi+v2, vi+2v2 and vo+v2 to vo+4v2.

The first group pumping stages 401 perform the pumping operations for boosting and outputting voltages to an outside, that is, the output pumping operations. The second group pumping stages 402 perform the pumping operations for boosting voltages, that is, the boosting pumping operations.

Therefore, since the pumping stage unit 203 shown in FIG. 4 include the second group pumping stages 402 for performing the boosting pumping operations, it is possible to reduce an area necessary for providing the target output voltages vo and vo1.

Also, since the pumping stage unit 203 has the first group pumping stages 401 for performing the output pumping operations, it is possible to output the output voltages vo and vo1 with reduced noise.

The plurality of pumping stages 401 and 402 shown in FIG. 4 may include pumping stages which are generally known in the art. That is, the plurality of pumping stages 401 and 402 may be configured to perform the pumping operations for the capacitor elements arranged therein, in synchronization with the first clock clk1 and the second clock clk2.

In the case where the capacitor element of a forwardly positioned pumping stage with a relatively low level of output voltage is formed to have the ONO structure, an area reduction effect may be achieved.

As aforementioned above, the capacitor element formed to have the ONO structure has a disadvantage that a breakdown voltage is low when compared to capacitor elements generally known in the art. Thus, the capacitor element arranged in a predetermined pumping stage (for example, the second group pumping stage 402 which outputs the voltage vi+v2) may be formed to have the ONO structure in consideration of the levels of the voltages outputted by the plurality of pumping stages 401 and 402.

FIG. 5 is a block diagram illustrating an exemplary embodiment of each of the second group pumping stages 402 and the first group pumping stages 401 shown in FIG. 4. The first group pumping stage 401 may include a capacitor element 501 as in the case of a general pumping circuit. The capacitor element 501 receives the first clock clk1 through one end thereof.

The other end of the capacitor element 501 is coupled with a pumping node 503. The voltage level of the pumping node 503 may vary according to the first clock clk1 which is applied to the one end of the capacitor element 501.

The first group pumping stage 401 may further include a first path control section 502 which controls a current path coupled to the pumping node 503 in response to the first clock clk1. The first path control section 502 may include a transistor for performing the function of a switch and a delay element.

The second group pumping stage 402 may be configured to include a capacitor element 504 as in the case of a general pumping circuit. The capacitor element 504 receives the second clock clk2 through one end thereof. The other end of the capacitor element 504 is coupled with a pumping node 506. The voltage level of the pumping node 506 may vary according to the swing of the second clock clk2 which is applied to the one end of the capacitor element 504.

The second group pumping stage 402 may be configured to further include a second path control section 505 which controls a current path coupled to the pumping node 506 in response to the second clock clk2. The second path control section 505 may include a transistor as a switch and a delay element.

The first clock clk1 and the second clock clk2 may be transmitted to the capacitor elements 501 and 504 via certain delay elements. However, this feature is not shown in FIG. 5 because it is well known to those skilled in the art.

The first and second group pumping stages 401 and 402 may perform the pumping operations according to the principle described below.

The second path control section 505 electrically connects the pumping node 506 and the pumping node 503 in response to the second clock clk2.

The voltage levels of the pumping nodes 506 and 503 are boosted from vi+v2 to vi+2v2 in response to the rising edge of the second clock clk2 which is applied to the one end of the capacitor element 504.

The second path control section 505 electrically disconnects the pumping node 506 and the pumping node 503 in response to the second clock clk2. Accordingly, even when the voltage level of the pumping node 506 is reduced from vi+2v2 to vi+v2 in response to the falling edge of the second clock clk2, the voltage level of the pumping node 503 may be maintained at vi+2v2.

The first path control section 502 electrically connects the pumping node 503 with an output node 507 in response to the first clock clk1.

The voltage levels of the pumping node 503 and the output node 507 are boosted from vi+2v2 to vi+2v2+v1 in response to the rising edge of the first clock clk1 which is applied to the one end of the capacitor element 501.

The first path control section 502 electrically disconnects the pumping node 503 and the output node 507 in response to the first clock clk1. Accordingly, even when the voltage level of the pumping node 503 is reduced from vi+2v2+v1 to vi+2v2 in response to the falling edge of the first clock clk1, the voltage level of the output node 507 may be maintained at vi+2v2+v1.

In the first and second group pumping stages 401 and 402 shown in FIG. 5, the capacitor elements 501 and 504 respectively receive the first clock clk1 and the second clock clk2 with different amplitudes.

While certain embodiments have been described above, it will be understood to those skilled in the art that the embodiments described are by way of example only. Accordingly, the pump circuit and the method for pumping a voltage in a semiconductor apparatus described herein should not be limited based on the described embodiments. Rather, the pump circuit and the method for pumping a voltage in a semiconductor apparatus described herein should only be limited in light of the claims that follow when taken in conjunction with the above description and accompanying drawings.

What is claimed is:

1. A pump circuit comprising:
a first clock generation unit configured to generate a first clock with a first amplitude by using an input clock and an external voltage;
a second clock generation unit configured to generate a second clock with a second amplitude larger than the first amplitude by using the input clock and an amplified voltage generated by amplifying the external voltage; and
a pumping stage unit configured to increase an input voltage using the first clock and the second clock and generate amplified output voltages.

2. The pump circuit according to claim 1,
wherein the pumping stage unit includes a plurality of pumping stages coupled in series,
wherein first group pumping stages among the plurality of pumping stages perform pumping operations using the first clock, and
wherein second group pumping stages among the plurality of pumping stages perform pumping operations using the second clock.

3. The pump circuit according to claim 2,
wherein the amplified output voltages are output voltages of the first group pumping stages.

4. The pump circuit according to claim 2,
wherein a first pumping stage among the plurality of pumping stages, which receives the amplification input voltage, is one of the first group pumping stages and performs a pumping operation for a capacitor element in synchronization with the first clock, and
wherein the capacitor element is formed to have an ONO (oxide-nitride-oxide) structure.

5. The pump circuit according to claim 1, wherein phases and cycles of the first clock and the second clock are the same with each other.

6. The pump circuit according to claim 1, further comprising:
an amplified voltage generation unit configured to generate the amplified voltage using the first clock and the external voltage.

7. The pump circuit according to claim 6,
wherein the amplified voltage generation unit generates the amplified voltage by performing a pumping operation for a capacitor element in synchronization with the input clock, and
wherein the capacitor element is formed to have an ONO structure.

8. The pump circuit according to claim 1,
wherein the pumping stage unit performs a pumping operation by using the first clock in performing a pumping operation for boosting a voltage and outputting an output to an outside of the pump circuit, and
wherein the pumping stage unit performs a pumping operation by using the second clock in performing a pumping operation for boosting a voltage and not outputting an output to an outside of the pump circuit.

9. The pump circuit according to claim 2,
wherein each of the first group pumping stages comprises a capacitor element and a first path control section,
wherein one end of the capacitor element receives the first is clock and the other end of the capacitor element is electrically connected with a pumping node, and
wherein the first path control section controls a current path coupled to the pumping node, in response to the first clock.

10. The pump circuit according to claim 2,
wherein each of the second group pumping stages comprises a capacitor element and a second path control section,
wherein one end of the capacitor element receives the second clock and the other end of the capacitor element is electrically connected with a pumping node, and
wherein the second path control section controls a current path coupled to the pumping node, in response to the second clock.

11. A pump circuit comprising:
one or more of first group pumping stages configured to perform pumping operations using a first clock; and
one or more of second group pumping stages configured to perform pumping operations using a second clock,
wherein the one or more of the first group pumping stages and the one or more of the second group pumping stages are coupled in series, and
wherein the amplitude of the second clock is larger than the amplitude of the first clock.

12. The pump circuit according to claim 11,
wherein output voltages of the one or more of the first group pumping stages are outputted to an outside.

13. The pump circuit according to claim 11, wherein phases and cycles of the first clock and the second clock are the same with each other.

14. The pump circuit according to claim 11, wherein each of the first group pumping stages comprises a capacitor element and performs the pumping operation by providing the first clock to one end of the capacitor element.

15. The pump circuit according to claim 11, wherein each of the second group pumping stages comprises a capacitor element and performs the pumping operation by providing the second clock to one end of the capacitor element.

16. A method for amplifying a voltage in a semiconductor apparatus, comprising:
receiving an input voltage;
outputting a first amplified voltage by increasing the input voltage using a second clock; and
outputting a second amplified voltage by increasing the first amplified voltage using a first clock,
is wherein the amplitude of the second clock is larger than the amplitude of the first clock.

17. The method according to claim 16, further comprising:
generating an amplified voltage with a voltage level higher than an external voltage by amplifying the external voltage using the first clock signal; and
generating the second clock signal using the amplified voltage.

18. The method according to claim 17,
wherein, in the generating of the amplified voltage, the amplified voltage is generated by performing a pumping operation for a capacitor element in synchronization with the first clock, and
wherein the capacitor element is formed to have an ONO structure.

19. The method according to claim 16, further comprising:
amplifying the amplification input voltage a number of times in series using the second clock with the second amplitude and outputting the first amplified voltage.
